(19) United States
(12) Patent Application Publication
(10) Pub. No.: US 2008/0303744 A1
(43) Pub. Date: Dec. 11, 2008

(54) PLASMA PROCESSING SYSTEM, ANTENNA, AND USE OF PLASMA PROCESSING SYSTEM

(75) Inventors: Masaki HIRAYAMA, Miyagi (JP); Tadahiro OHMI, Miyagi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: TOKYO ELECTRON LIMITED, Tokyo (JP); Tohoku University, Sendai-shi (JP)

(21) Appl. No.: 12/137,124

(22) Filed: Jun. 11, 2008

(30) Foreign Application Priority Data
Jun. 11, 2007 (JP) 2007-153544
May 29, 2008 (JP) 2008-140382

(51) Int. Cl. H01Q 1/36; C23C 16/54; C23C 16/452; B08B 6/00

(52) U.S. Cl. 343/900; 118/723 I; 427/569; 134/1.1

(57) ABSTRACT

A plasma processing system 10 includes a processing chamber 100, a microwave source 900 that outputs a microwave, an inner conductor of a coaxial waveguide 315a that transfers the microwave, a through-hole 305a, a dielectric plate 305 that transmits the microwave transferred through the inner conductor 315a and discharges it into a processing chamber 100, and a metal electrode 310 that is coupled to the inner conductor 315a via the through-hole 305a, the metal electrode 310 being exposed on the surface of the dielectric plate 305 that faces the substrate with at least a portion of the metal electrode 310 being adjacent to the surface of the dielectric plate 305 that faces the substrate. A surface of the exposed surface of the metal electrode 310 is covered by the dielectric cover 320.

### CROSS-REFERENCE TO RELATED APPLICATION

The present invention contains subject matter related to Japanese Patent Application JP 2007-153544, filed in the Japan Patent Office on Jun. 11, 2007 and Japanese Patent Application JP 2008-140382, filed in the Japan Patent Office on May 29, 2008, the entire contents of which being incorporated herein by reference.

### FIELD OF THE INVENTION

The present invention relates to a plasma processing system that excites a gas using an electromagnetic wave and applies a plasma process to a target object, and more particularly, to a plasma processing system that includes an antenna for supplying a low-frequency electromagnetic wave into the processing chamber.

### BACKGROUND OF THE INVENTION

Various methods have been developed to use a waveguide or an coaxial waveguide to introduce an electromagnetic wave into a plasma processing chamber. One of the methods uses a coaxial waveguide having a cylindrical center conductor therein and a dielectric disc having a circular through-hole formed at the center thereof, and the bottom of the center conductor being fitted in the through-hole, and the bottom end of the center conductor having a metal cap fitted thereon for excitation of the plasma. The metal cap has protection caps attached to the bottom surface and the peripheral surface thereof, respectively. The protection cap serves to reduce direct exposure of these surfaces in the plasma generation chamber. The protection cap may reduce electric field concentration at the metal cap due to the plasma generated in the plasma generation chamber, and thus avoid the metal cap damage.

### SUMMARY OF THE INVENTION

When, unfortunately, the entire metal cap is covered by the protection cap and one surface of the metal cap such as the bottom surface or the peripheral surface is in close contact with the protection cap, a gap may exist on other surfaces of the metal cap, an abnormal discharge may be generated in the gap, and the discharge may make the plasma nonuniform and unstable. In contrast, it is costly to accurately machine the metal cap and the protection cap to bring any surface of the metal cap into close contact with the protection cap to eliminate the gap.

To solve the issues, an aspect of the present invention provides a plasma processing system that excites a gas using an electromagnetic wave and applies a plasma process to a target object, the system including: a processing chamber; an electromagnetic source that outputs an electromagnetic wave; a conductor rod that transfers the electromagnetic wave from the electromagnetic source; a dielectric plate that has a through-hole formed thereon, the dielectric plate transmitting the electromagnetic wave transferred by the conductor rod into the processing chamber; and a metal electrode that is coupled to the conductor rod via the through-hole formed on the dielectric plate, at least a portion of the metal electrode being adjacent to the surface of the dielectric plate that faces the target object, and the metal electrode being exposed on the surface of the dielectric plate that faces the target object, a surface of the exposed surface of the metal electrode being covered by a dielectric cover.

According to this configuration, a portion of the exposed surface of the metal electrode is covered by a dielectric cover. This may reduce the electric field near the metal electrode, thereby increasing the plasma uniformity. When two or more surfaces are machined, a gap may occur therebetween because of poor machining accuracy. The gap may generate an abnormal discharge.

According to the configuration, however, a surface of the exposed portion of the metal electrode is covered by a dielectric cover. In this way, when only a surface of the exposed portion of the metal electrode, such as the bottom surface or the peripheral surface of the metal electrode, is covered by the dielectric cover, the metal electrode and the dielectric cover may be in close contact. This may eliminate the gap between the metal electrode and the dielectric cover, thereby reducing the abnormal discharge and generating a uniform and stable plasma. Because the highly accurate machining is unnecessary, the cost may be reduced.

To solve the issues, another aspect of the present invention provides a plasma processing system that excites a gas using an electromagnetic wave and applies a plasma process to a target object, the system including: a processing chamber; an electromagnetic source that outputs an electromagnetic wave; a conductor rod that transfers the electromagnetic wave from the electromagnetic source; a dielectric plate that has a through-hole formed thereon, the dielectric plate transmitting the electromagnetic wave transferred by the conductor rod into the processing chamber; and a metal electrode that is coupled to the conductor rod via the through-hole formed on the dielectric plate, at least a portion of the metal electrode being adjacent to the surface of the dielectric plate that faces the target object, and the metal electrode being exposed on the surface of the dielectric plate that faces the target object, the exposed surface of the metal electrode does not include a surface that is generally parallel to the target object.

The inventors performed a unique simulation and found the following results. As shown in FIG. 7, on the metal electrode exposed on the surface of the dielectric plate facing the target object, the surface (surface C) parallel to the target object induces a high electric field.

The exposed surface of the metal electrode may therefore be formed to have no surface generally parallel to the target object to reduce the electric field near the metal electrode and increase the uniformity of the plasma.

To solve the issues, another aspect of the present invention provides an antenna including: a conductor rod that transfers an electromagnetic wave; a dielectric plate that has a through-hole formed therein, the dielectric plate transmitting the electromagnetic wave transferred by the conductor rod into the processing chamber; and a metal electrode that is coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object, a surface of the exposed surfaces of the metal electrode being covered by a dielectric cover.

To solve the issues, another aspect of the present invention provides an antenna including: a conductor rod that transfers an electromagnetic wave; a dielectric plate that has a through-hole formed therein, the dielectric plate transmitting the electromagnetic wave transferred by the conductor rod into the processing chamber; and a metal electrode that is coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object, the exposed surface of the metal electrode does not include a surface that is generally parallel to the target object.

To solve the issues, another aspect of the present invention provides a method of using a plasma processing system, the method including: outputting an electromagnetic wave at a frequency of 1 GHz or less from an electromagnetic source, transferring the electromagnetic wave through a conductor rod; transmitting the electromagnetic wave transferred from the conductor rod through a dielectric plate held on an interior wall of a processing chamber and discharging the electromagnetic wave into the processing chamber, the dielectric plate being held on the interior wall by a metal electrode, the metal electrode being coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object; and exciting a process gas introduced into the processing chamber using the discharged electromagnetic wave and applying a desired plasma processing on the target object.

To solve the issues, another aspect of the present invention provides a method of cleaning a plasma processing system, the method including: outputting an electromagnetic wave at a frequency of 1 GHz or less from an electromagnetic source, transferring the electromagnetic wave through a conductor rod; transmitting the electromagnetic wave transferred from the conductor rod through a dielectric plate held on an interior wall of a processing chamber and discharging the electromagnetic wave into the processing chamber, the dielectric plate being held on the interior wall by a metal electrode, the metal electrode being coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object; and exciting a cleaning gas introduced into the processing chamber using the discharged electromagnetic wave and cleaning the plasma processing chamber.

Therefore, an electromagnetic wave at a frequency of 1 GHz or less, for example, may be used to excite a uniform and stable plasma from a single F-based gas. The single F-based gas may not be effective in exciting a uniform and stable plasma using a certain degree of power of an electromagnetic wave at a frequency of 2.45 GHz because the surface wave is not spread. Practical power of the electromagnetic wave may thus be used to excite a cleaning gas to generate a plasma. The plasma may clean the interior of the plasma processing system.

### BRIEF DESCRIPTION OF THE DRAWINGS

FIG. 1 is a vertical cross-sectional view of a plasma processing system according to a first embodiment of the present invention;

FIG. 2 illustrates the ceiling of the plasma processing system in the first embodiment;

FIG. 3 illustrates a waveguide divider in the first embodiment;

FIG. 4 illustrates a fastening mechanism of a dielectric plate and the vicinity thereof in the first embodiment;

FIG. 5 illustrates a split plate in the first embodiment;

FIG. 6 illustrates a metal electrode and the vicinity thereof in the first embodiment;

FIG. 7 shows the relationship between the metal electrode shape and the electric field strength in the first embodiment;

FIG. 8 shows a modification of the metal electrode in the first embodiment;

FIG. 9 shows another modification of the metal electrode in the first embodiment;

FIG. 10 shows another modification of the metal electrode in the first embodiment;

FIG. 11 shows another modification of the metal electrode in the first embodiment;

FIG. 12 shows the cross-sectional view taken along the line X-X in FIG. 11;

FIG. 13 shows a profile of microwave power density versus plasma electron density;

FIG. 14 shows another modification of the system;

FIG. 15 shows simulation results for an optimized metal electrode shape (basic shape);

FIG. 16 shows other simulation results for the optimized metal electrode shape (basic shape);

FIG. 17 shows simulation results for an optimized metal electrode shape (cone);

FIG. 18 shows other simulation results for the optimized metal electrode shape (cone);

FIG. 19 shows other simulation results for the optimized metal electrode shape (cone);

FIG. 20 shows simulation results for an optimized metal electrode shape (hemisphere);

FIG. 21 shows simulation results for the optimized dielectric cover shape;

FIG. 22 shows other simulation results for the optimized dielectric cover shape; and

FIG. 23 shows other simulation results for the optimized dielectric cover shape.

### DESCRIPTION OF THE EMBODIMENTS

### First Embodiment

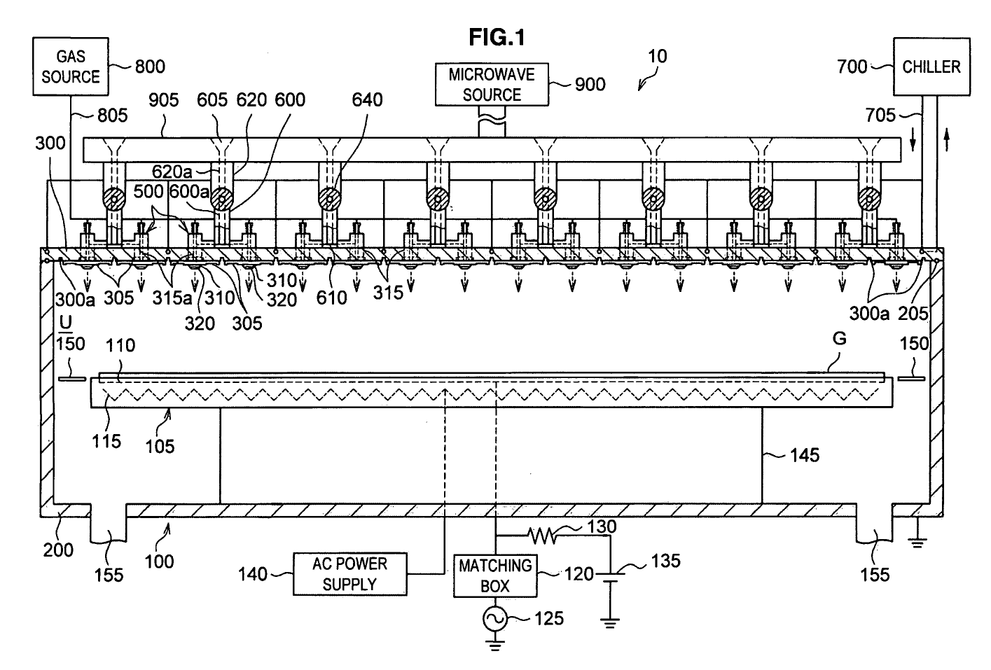

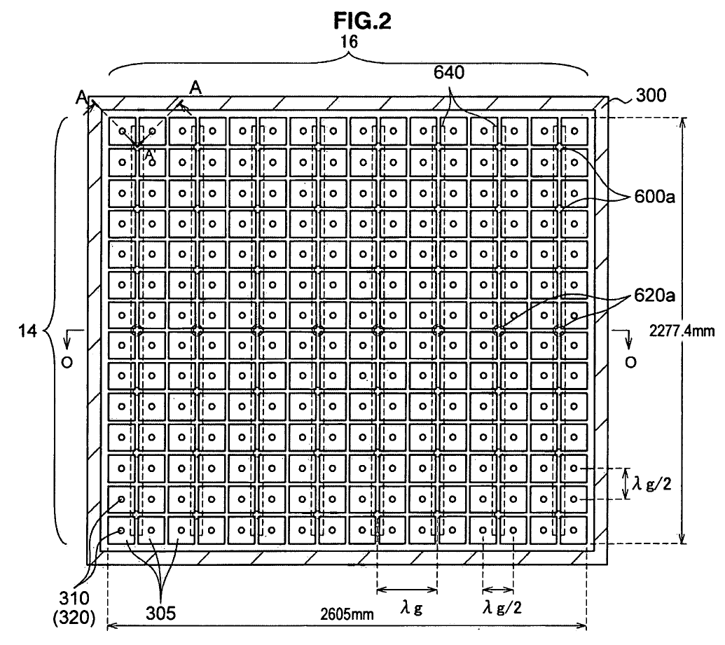

With reference to the accompanying drawings, a plasma processing system according to a first embodiment of the present invention will be described below. FIG. 1 is a vertical cross-sectional view of the system (taken along the line O-O in FIG. 2). FIG. 2 shows the ceiling of the processing chamber. Note that, in the following discussion and accompanying drawings, the elements having the same configuration and function are provided with the same reference symbols and their description are omitted.

### (Configuration of Plasma Processing System)

A plasma processing system 10 includes a processing chamber 100 in which a plasma process is applied to a glass substrate (“substrate G”). The processing chamber 100 includes a chamber main portion 200 and a lid 300. The chamber main portion 200 has a bottom-closed cube shape with an opening formed on the top thereof. The opening is closed by the lid 300. On the contact surface between the chamber main portion 200 and the lid 300 is provided with an O-ring 205. The O-ring 205 seals the chamber main portion 200 and the lid 300 and thus forms a processing chamber U. The chamber main portion 200 and the lid 300 are made of, for example, metal such as aluminum. They are electrically grounded.

The processing chamber 100 contains a susceptor 105 (stage) to support the substrate G. The susceptor 105 is made of, for example, nitride aluminum. The susceptor 105 contains a power feeding portion 110 and a heater 115.

The power feeding portion 110 is connected to a high-frequency power supply 125 via a matching box 120 (such as a capacitor). The power feeding portion 110 is also connected to a high-voltage dc power supply 135 via a coil 130. The matching box 120, the high-frequency power supply 125, the coil 130, and the high-voltage dc power supply 135 reside outside the processing chamber 100. The high-frequency power supply 125 and the high-voltage dc power supply 135 are grounded.

The power feeding portion 110 uses high-frequency electric power from the high-frequency power supply 125 to apply a predetermined bias voltage into the processing chamber 100. The power feeding portion 110 uses dc voltage from the high-voltage dc power supply 135 to electrostatically chuck the substrate G.

The heater 115 is connected to an AC power supply 140 outside the processing chamber 100. The heater 115 uses AC voltage from the AC power supply 140 to keep the substrate G at a predetermined temperature. The susceptor 105 is supported by a support member 145. The susceptor 105 is surrounded by a baffle plate 150 to control the gas flow in the processing chamber U to the preferable state.

At the bottom of the processing chamber 100 is provided a gas exhaust pipe 155. Outside the processing chamber 100 is provided a vacuum pump (not shown). The vacuum pump exhausts gases from the processing chamber 100 through the gas exhaust pipe 155. The processing chamber U is thus evacuated to a desired degree of vacuum.

On the lid 300 are provided a plurality of dielectric plates 305, a plurality of metal electrodes 310, and a plurality of inner conductors 315a of coaxial waveguides. With reference to FIG. 2, each dielectric plate 305 is a generally-square plate of 148 mm×148 mm and made of alumina (Al₂O₃). The dielectric plates 305 are arranged in a matrix at regular intervals of an integral multiple (here, once) of λg/2. The λg is the wavelength of a coaxial waveguide divider 640 (the λg is 328 mm at 915 MHz). The dielectric plates 305 of 224 (=14×16) are thus uniformly disposed on the ceiling of 2277.4 mm×2605 mm of the processing chamber 100.

Each dielectric plate 305 has a symmetrical shape and may thus easily generate a uniform plasma therein. The dielectric plates 305 are disposed at regular intervals of an integral multiple of λg/2. The inner conductors 315a of the coaxial waveguides may therefore be used to introduce an electromagnetic wave to generate a uniform plasma.

Returning to FIG. 1, the metal surface of the lid 300 has a groove 300a formed thereon. The groove 300a may reduce the propagation of the conductor surface wave. Note that the conductor surface wave is a wave that propagates between the metal surface and a plasma.

Each inner conductor 315a passes through the dielectric plate 305 and has a metal electrode 310 at the end. The metal electrode 310 is exposed to the substrate G. The inner conductor 315a and the metal electrode 310 hold the dielectric plate 305. The surface of the metal electrode 310 facing the substrate is provided with a dielectric cover 320. The cover 320 may reduce the electric field concentration.

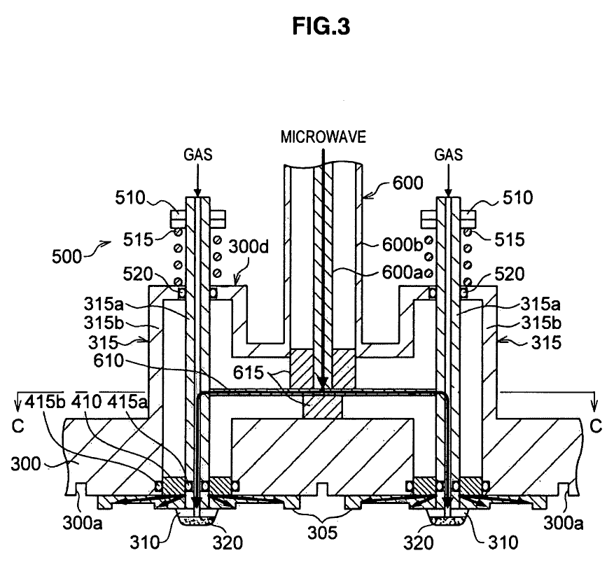

FIG. 3 shows the cross-sectional view taken along the line A-A′-A in FIG. 2. The coaxial waveguide 315 includes the cylindrical inner conductor (shaft) 315a and an outer conductor 315b. The tube 315 is thus made of metal (preferably copper). Between the lid 300 and the inner conductor 315a is provided a dielectric ring 410, through which the inner conductor 315a passes at the center. The dielectric ring 410 has an inner surface and a peripheral surface. The inner surface has an O-ring 415a thereon. The peripheral surface has an O-ring 415b thereon. The O-rings 415a and 415b may vacuum seal the processing chamber U.

The inner conductor 315a passes through a lid portion 300d and out of the processing chamber 100. The inner conductor 315a is fastened by a fastening mechanism 500. The mechanism 500 includes a coupling portion 510, a spring member 515, and a shorting portion 520. The fastening mechanism 500 uses elastic force of the spring member 515 to lift the inner conductor 315a away from the processing chamber 100. Note that the lid portion 300d is a portion that resides on the upper surface of the lid 300 near the portion that lifts the inner conductor 315a. The lid portion 300d is integrated with the lid 300 and the outer conductor 315b.

The shorting portion 520 resides at the portion of the coaxial waveguide 315 through which the inner conductor 315a passes. The shorting portion 520 electrically connects the inner conductor 315a of the coaxial waveguide 315 and the lid portion 300d. The shorting portion 520 includes a shield spiral that allows the inner conductor 315a to slide vertically. The shorting portion 520 may also include a metal brush.

Heat flows into the metal electrode 310 from the plasma. The shorting portion 520 and the inner conductor 315a may efficiently release the heat to the lid. This may reduce the heating of the inner conductor 315a, thereby reducing the degradation of the O-rings 415a and 415b adjacent to the inner conductor 315a. The shorting portion 520 may also reduce the transfer of the microwave to the spring member 515 via the inner conductor 315a. This may reduce the abnormal discharge or power loss near the spring member 515. The shorting portion 520 may also reduce the shaft swing of the inner conductor 315a and thus securely hold the conductor 315a.

An O-ring (not shown) may reside between the lid portion 300d and the inner conductor 315a at the shorting portion 520 and between a dielectric material 615 (described below) and the lid portion 300d to provide a vacuum seal. An inert gas may then be filled in the space of the lid portion 300d to reduce introduction of the impurities of the atmosphere into the processing chamber.

In FIG. 1, a chiller 700 is connected to a coolant pipe 705. The coolant from the chiller 700 circulates in the coolant pipe 705 and back to the chiller 700, thus keeping the processing chamber 100 at a desired temperature. A gas source 800 supplies a gas through a gas line 805. The gas is then introduced into the processing chamber via the gas flow channel in the inner conductor 315a shown in FIG. 3.

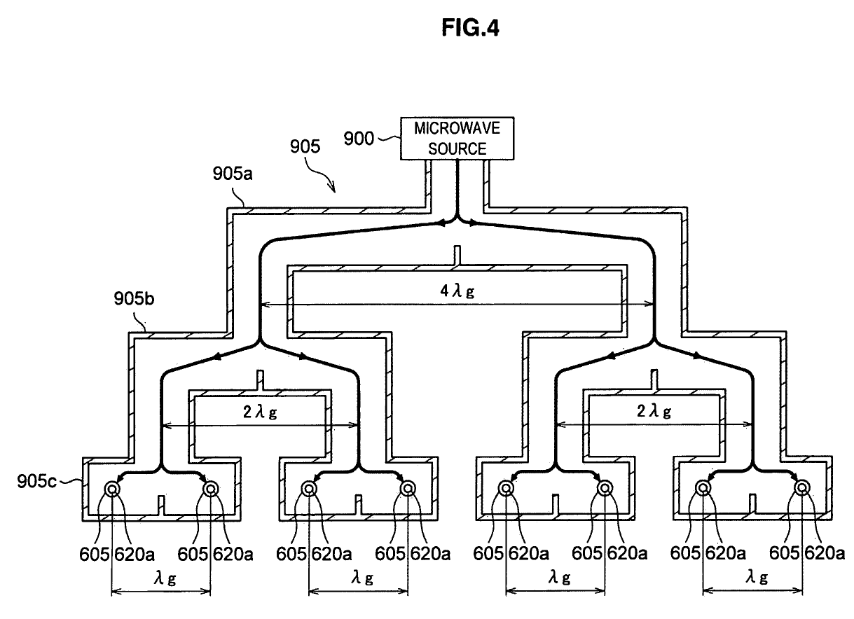

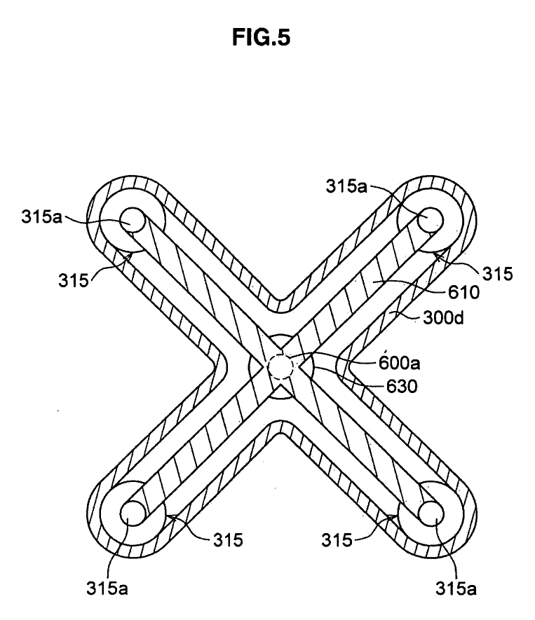

Two microwave sources 900 output a microwave of 120 kW (=60 kW×2 (2 W/cm²)). The microwave is supplied into the processing chamber through the dielectric plates 305 after transferred through the following components: a waveguide divider 905 (see FIG. 4), eight coaxial to waveguide adapters 605, eight coaxial waveguides 620, coaxial waveguides 600, the tubes 600 being coupled to eight coaxial waveguide dividers 640 (see FIG. 2) provided in parallel on the backside of the system 10 in FIG. 1 (seven tubes 600 to each tube 640), a split plate 610 (see FIG. 5), and the coaxial waveguide 315. After discharged into the processing chamber U, the microwave excites the process gas from the gas source 800. The resulting plasma is used to carry out a desired plasma process on the substrate G.

### (Holding of Dielectric Plate by Metal Electrode)

A detailed description is given of the configuration of the antenna portion (the dielectric plate 305, the metal electrode 310, and the coaxial waveguide 315) of the plasma processing system 10 in this embodiment, and a holding mechanism of the dielectric plate 305 using the metal electrode 310.

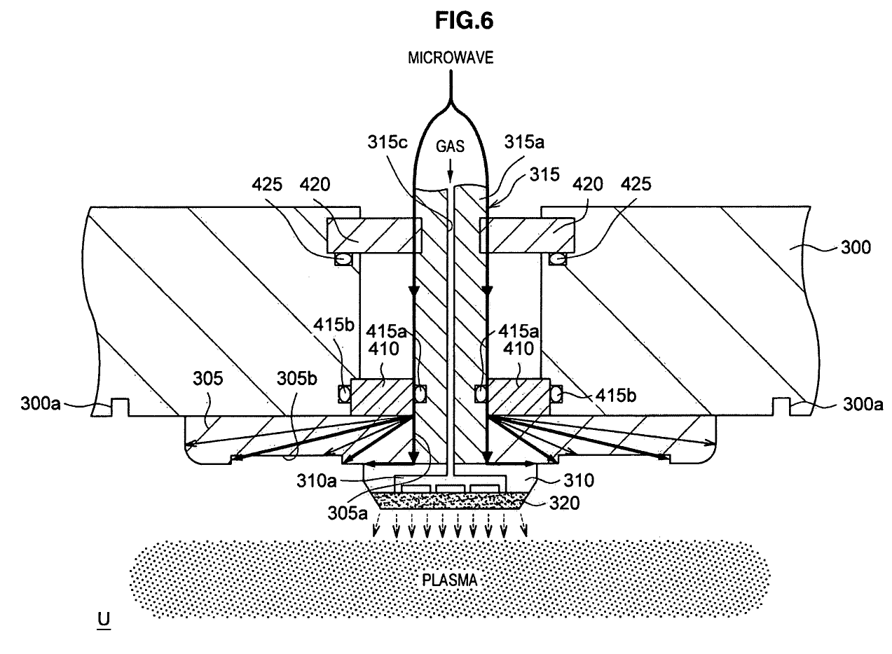

FIG. 6 enlarges the vicinity of the metal electrode 310. With reference to FIGS. 3 and 6, the coaxial waveguides 315 and 600 include the cylindrical inner conductors 315a and 600a, and the outer conductors 315b and 600b, respectively. All of the conductors are made of metal. The inner conductor 315a is an example of a conductor rod. Particularly, in this embodiment, the coaxial waveguides 315 and 600 are made of copper. The copper has high thermal conductivity and high electrical conductivity. The coaxial waveguides 315 and 600 may thus release heat from the microwave and the plasma and transfer the microwave efficiently.

The metal electrode 310 is made of metal such as aluminum (Al). When the metal electrode 310 is exposed to the plasma, the electric field concentrates on the metal electrode 310 near the feed point. The electric field may then generate a plasma on the metal electrode 310 with higher density than that on the surface of the dielectric plate 305. The plasma may reduce the plasma uniformity and also etch the metal electrode 310, thus generating metal contamination. Particularly, a higher electric field occurs in the plane generally parallel to the substrate G.

### (Simulation)

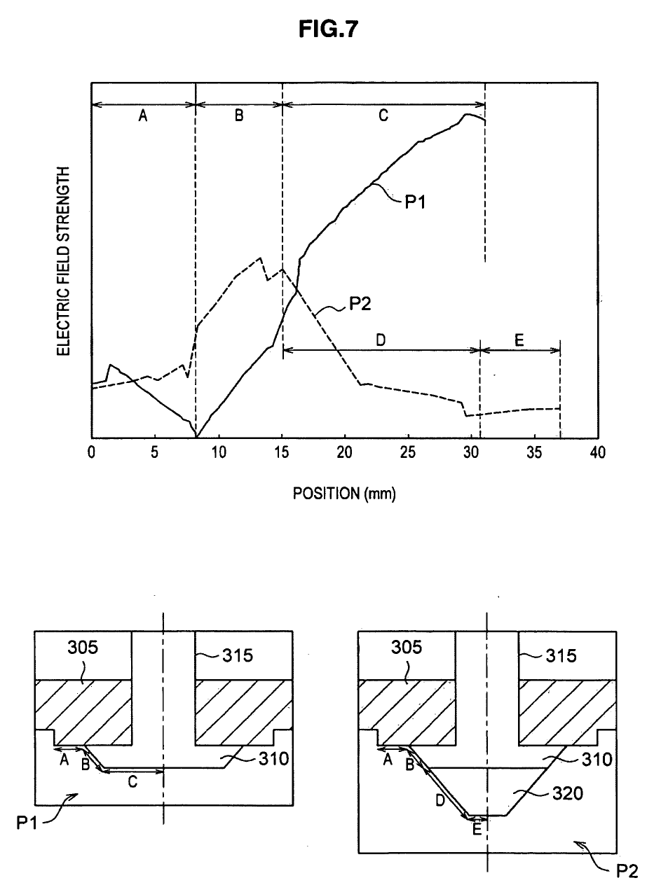

With reference to FIG. 7, a description is given of the electric field strength of the microwave in the sheath near the surfaces A-C and A-E of the simulation models P1 and P2, respectively. The inventors simulated the electric field strength near the surfaces A to C and the surfaces A to E (i.e., the electric field strength of the microwave in the sheath) for two conditions P1 and P2. The first condition P1 is that, of the exposed portion of the metal electrode 310, the surface C parallel to the substrate G is directly exposed to the substrate G. The second condition P2 is that, of the exposed portion of the metal electrode 310, the surface parallel to the substrate G is covered by the dielectric cover 320. With reference to FIG. 7, the graph of the simulation results shows that, of the surfaces of the metal electrode 310, the surface C exposed in parallel to the substrate G induces a significantly high electric field.

Describing in more detail, when the surface C parallel to the substrate G is exposed to the plasma (P1), the electric field near the bottom surface A of the dielectric plate 305 is relatively low. While the electric field near the side surface B of the exposed portion of the metal electrode 310 increases away from the surface A, the field is lower than that near the surface C parallel to the substrate G. The electric field near the surface C parallel to the substrate G is significantly higher than those near other surfaces A and B.

The inventors then simulated the electric field strength for the condition P2 in that the surface C parallel to the substrate G is covered by the alumina dielectric cover 320. The results showed that the flat portion covered by the dielectric cover 320 may significantly decrease the electric field at the flat portion. The electric field is also higher at the oblique surface B. The field strength is, however, only about half the strength obtained when the flat portion is not covered by the dielectric cover 320. The inventors thus proved that the flat portion may be covered by the dielectric cover 320 to reduce the plasma concentration, thereby generating a more uniform plasma.

From comparison between P1 and P2, the inventors also recognized that the surface C parallel to the substrate G may be covered by the dielectric cover 320 to reduce the electric field near the metal electrode, thereby increasing the uniformity of the plasma.

In FIG. 6, therefore, of the surfaces of the exposed portion of the metal electrode 310, the surface generally parallel to the substrate G is covered by the dielectric cover 320. Particularly, only one surface of the metal electrode such as the bottom surface or the peripheral surface is covered by the dielectric cover 320. This may thus bring the metal electrode 310 and the dielectric cover 320 into close contact with each other. No gap thus exists between the metal electrode 310 and the dielectric cover 320, thereby reducing the abnormal discharge and generating a uniform and stable plasma. Because the highly accurate machining is unnecessary, the cost may be reduced. The dielectric cover 320 is made of porous ceramic.

The metal electrode 310 is coupled to the inner conductor 315a in the coaxial waveguide 315 via a through-hole 305a at a generally center of the dielectric plate 305. The metal electrode 310 is exposed on the surface of the dielectric plate 305 facing the substrate. The metal electrode 310 has a larger diameter than the inner conductor 315a. The surface of the metal electrode 310 that is parallel to the substrate is partially adjacent to the surface of the dielectric plate 305 that is parallel to the substrate G. The dielectric plate 305 is thus held by the metal electrode 310 from the substrate side. The plate 305 is also raised by the inner conductor 315a. The plate 305 is thus securely fastened to the interior wall of the processing chamber 100.

The metal electrode 310 projects from the inner conductor 315a of the coaxial waveguide 315 and is exposed on the surface of the dielectric plate 305 facing the substrate. Because the metal electrode 310 is made of metal, it has higher mechanical strength than the dielectric member. The metal electrode 310 may thus securely hold the dielectric plate 305 in a structural and a material point of view.

With reference to FIG. 6, the coaxial waveguide 315 includes a gas introduction path 315c passing through the inner conductor 315a. The gas source 800 in FIG. 1 communicates with the gas introduction path 315c via the gas line 805. The gas introduction path 315c communicates with a gas passage 310a in the metal electrode 310. The gas passage 310a branches into two annular channels. A gas passing through the channels is discharged from the bottom surface of the metal electrode 310 to the dielectric cover 320.

After flowing into the dielectric cover 320, the gas flows through space between pores of the porous ceramic forming the dielectric cover 320. During the flow, the gas reduces the speed. The gas is then introduced uniformly at a reduced speed into the processing chamber U from the whole surface of the dielectric cover 320. When the gas flows regularly in a laminar fashion, a uniform and good process may be achieved.

The surface of each dielectric plate 305 facing the substrate is formed generally square and symmetrical about the metal electrode 310. The microwave is thus discharged uniformly from the dielectric plates 305 disposed on the whole ceiling. A more uniform plasma may thus be generated under the dielectric plate 305. Each dielectric plate 305 is made of alumina (Al₂O₃).

### (Optimum Shape of Metal Electrode and Dielectric Cover)

The inventors simulated the optimum shapes of the metal electrode 310 and the dielectric cover 320 made of alumina to reduce the abnormal discharge.

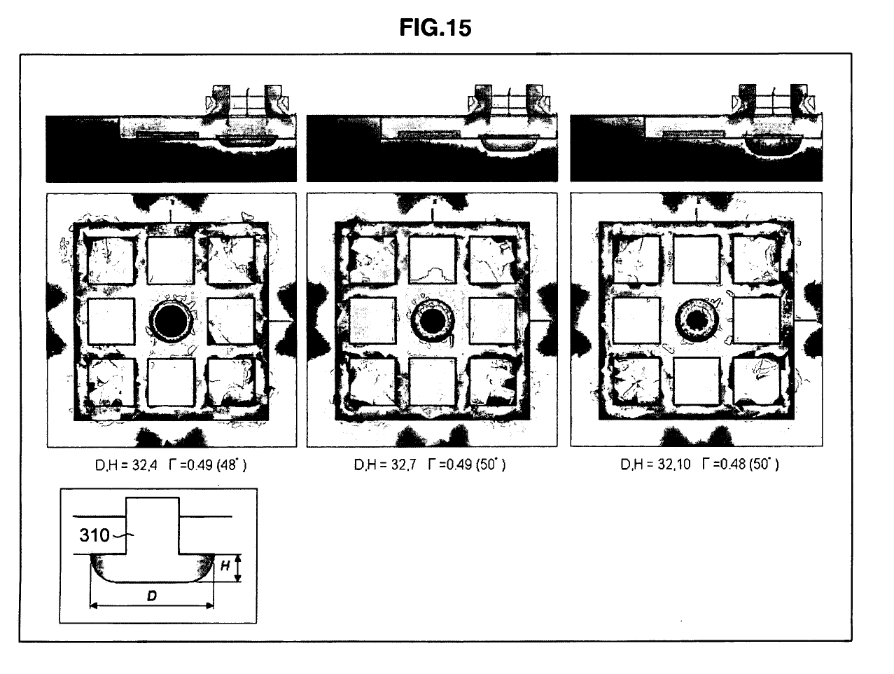

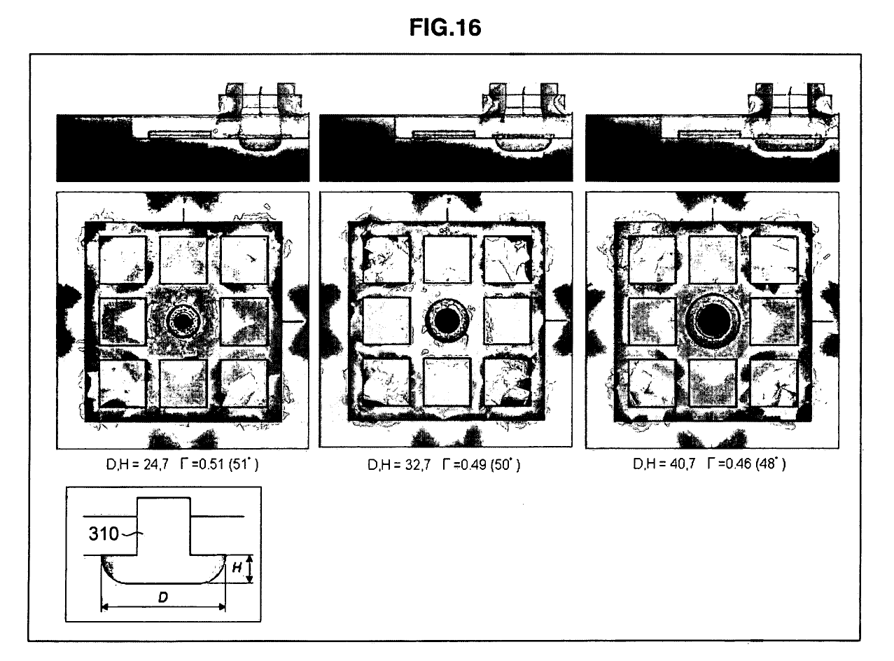

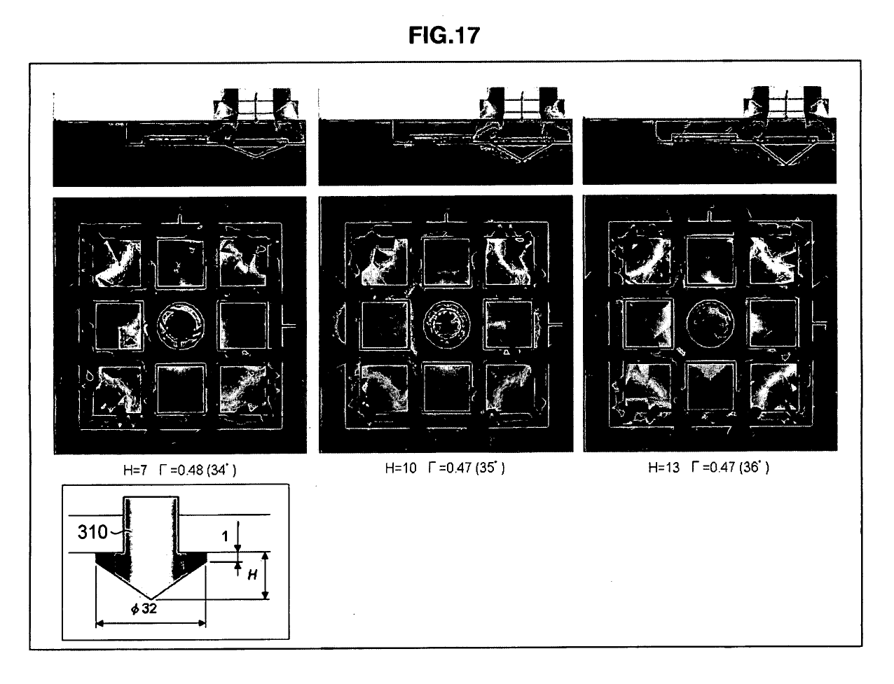

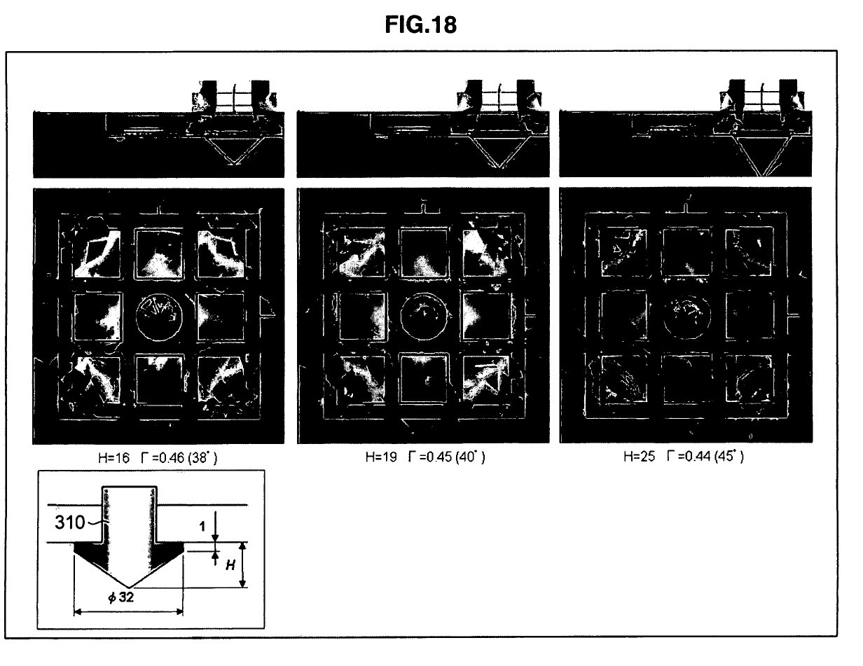

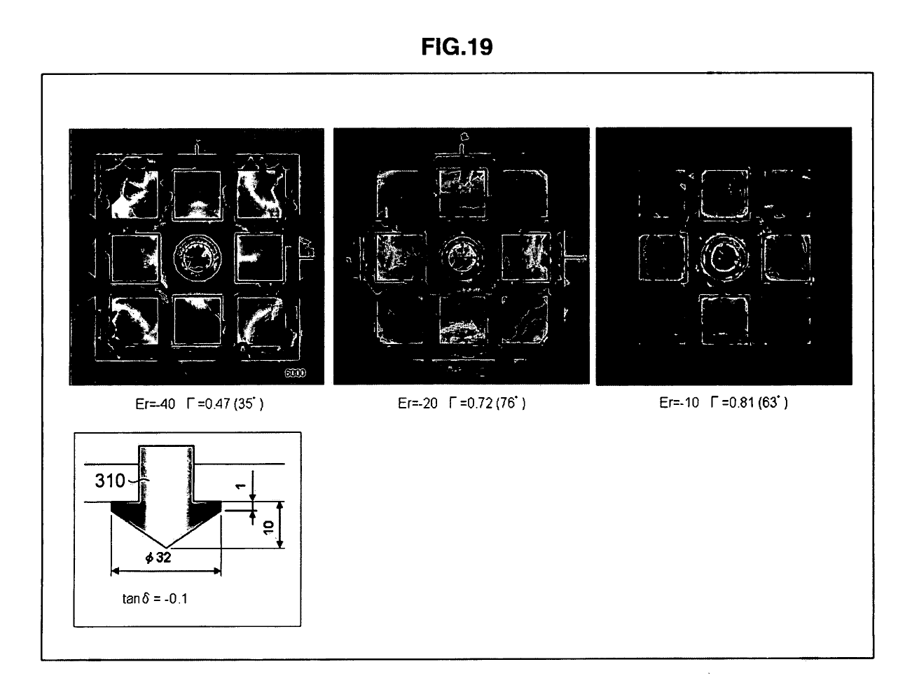

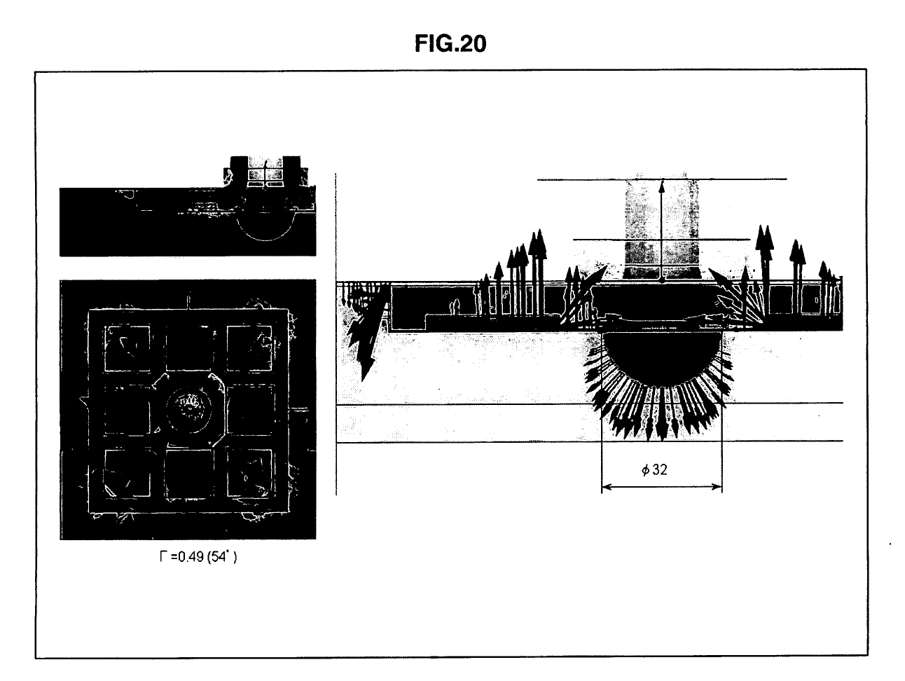

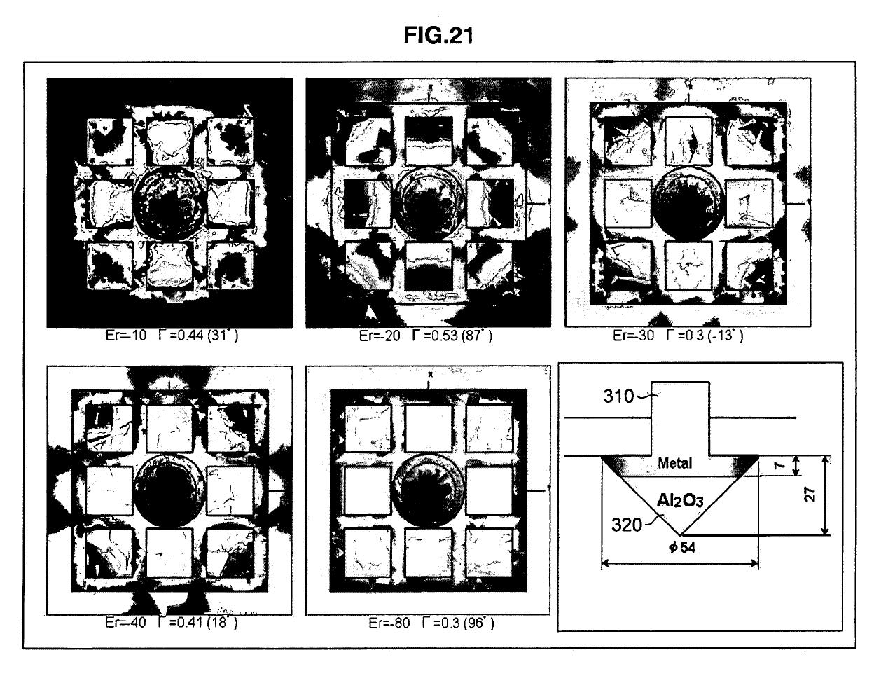

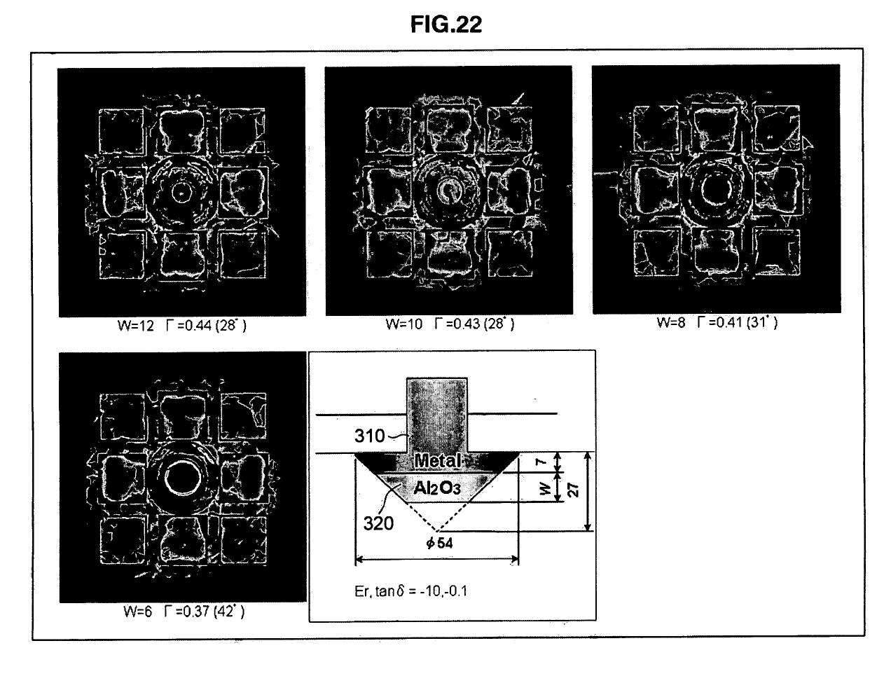

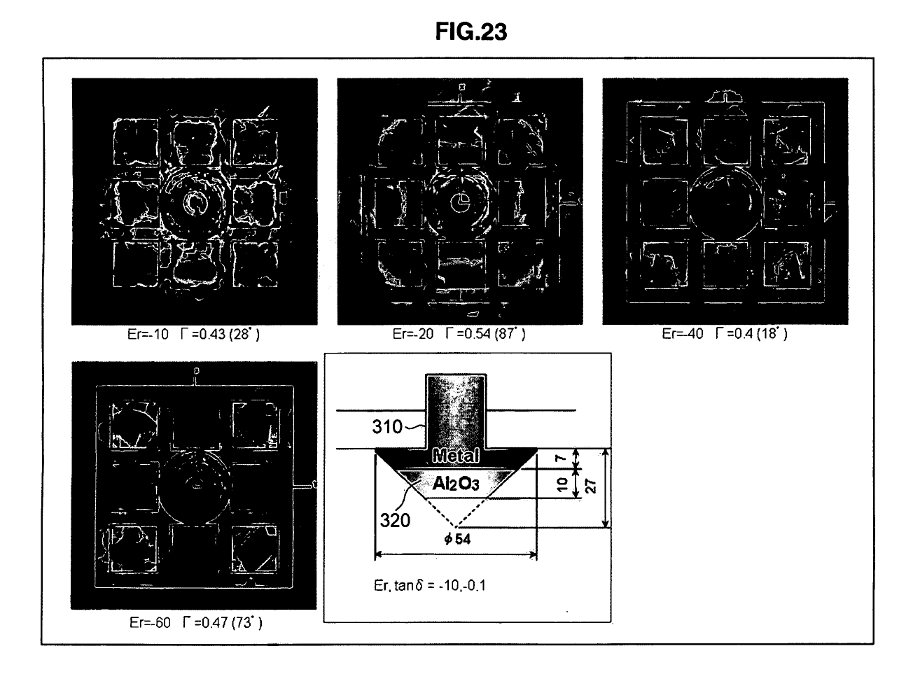

Simulations were performed with respect to the following shapes of the metal electrode 310: a basic shape having a width D, a height H, and an rounded end portion (FIGS. 15 and 16); a cone having a diameter of 32 mm and a height H (FIGS. 17 and 18); a cone having a diameter of 32 mm and a height of 10 mm (FIG. 19); and a hemisphere (FIG. 20). Simulations were performed with respect to a combined shape of the metal electrode 310 and the dielectric cover 320 for the dielectric covers 320 having a cone (FIG. 21) and a cone with a flat end (FIGS. 22 and 23).

### (Simulation Results)

With reference to FIGS. 15 to 23, the simulation results of the electric field distribution under the metal electrode 310 and the dielectric plate 305 are described below. First, under the above simulation conditions, the inventors performed a simulation with respect to a fixed width D of 32 mm and a varied height H of 4 mm, 7 mm, and 10 mm. FIG. 15 shows the electric field strength under the dielectric plate 305 in this case. Γ represents the absolute value of the reflection coefficient (a phase in parentheses). The reflection coefficient is an indicator that represents the reflection of the microwave on the metal electrode.

From the results in FIG. 15, the inventors recognized that the basic shape induces a high electric field in the horizontal plane under the metal electrode 310. The inventors also recognized that the electric field concentration is not reduced by variation of the height of the metal electrode 310.

With reference to FIG. 16, the inventors then simulated the field with respect to a fixed height H of 7 mm and a varied width D (the metal electrode diameter) of 24 mm, 32 mm, and 40 mm. The results showed, however, no reduction of the electric field concentration in the horizontal plane under the metal electrode.

With reference to FIG. 17, the inventors then simulated the field with respect to the metal electrode 310 of a cone and a varied height H of 7 mm, 10 mm, and 13 mm. The results showed that the electric field concentration is reduced and particularly it is difficult for the field concentrate to occur on the oblique surface of the metal electrode 310. The results also showed that for the height H of 7 mm, 10 mm, and 13 mm, the higher the metal electrode 310 is, the less the electric field concentration is.

With reference to FIG. 18, however, the results showed that for a height H of 16 mm, 19 mm, and 25 mm, the electric field increases again at the end of the metal electrode 310.

With reference to FIG. 19, the inventors then simulated the electric field distribution under the dielectric plate 305 with respect to the metal electrode 310 of a cone and a varied plasma dielectric constant ∈ᵣ. The cone diameter of the metal electrode 310 was fixed to 32 cm and the height fixed to 10 mm.

The dielectric dissipation factor T_{δ} was assumed to be −0.1. The dielectric constant ∈ᵣ and the dielectric dissipation factor T_{δ} of the plasma represent the state of the plasma. The dielectric constant ∈ᵣ of the plasma represents the polarization of the plasma. The dielectric dissipation factor T_{δ} of the plasma represents the charge loss by the resistance in the plasma generated by the excited gas.

In FIG. 19, the dielectric constant ∈ᵣ of the plasma varies as −40, −20, and −10. The higher dielectric constant ∈ᵣ of the plasma means the higher density of the plasma. From the results in FIG. 19, the inventors recognized that the lower the plasma density is, the higher the electric field of the metal electrode 310 is and the less the microwave extends.

With reference to FIG. 20, the inventors then simulated the electric field with respect to the metal electrode 310 of a hemisphere with a diameter of 32 mm. Again, the electric field concentration is not observed under the metal electrode 310 or the dielectric plate 305. The hemisphere metal electrode 310 is, however, higher than the cone metal electrode 310. Additionally, it is harder to machine the metal electrode 310 into a hemisphere than into a cone.

With reference to FIG. 21, the inventors then simulated the electric field for the following condition. The surface of the metal electrode 310 that is parallel to the target object is provided with the dielectric cover 320 of a cone. A generally-cone shape is thus provided to the exposed surfaces of the metal electrode 310 and the dielectric cover 320. It was assumed that the bottom surface of the metal electrode 310 has a diameter of 54 mm and a height of 7 mm, and the height from the bottom surface of the metal electrode 310 to the top of the dielectric cover 320 is 27 mm. Again, the electric field concentration was not observed near the metal electrode 310.

With reference to FIGS. 22 and 23, the inventors then simulated the electric field concentration with respect to the dielectric cover 320 having a flat end. In FIG. 22, it is assumed that the bottom surface of the metal electrode 310 has a diameter 54 mm and a height of 7 mm, and the dielectric cover 320 has a varied height W of 12 mm, 10 mm, 8 mm, and 6 mm. The inventors thus recognized that the electric field concentration is not observed when the thickness of the dielectric cover is 10 mm or more.

The inventors then assumed the model in FIG. 23. In FIG. 23, it is assumed that the bottom surface of the metal electrode 310 has a diameter of 54 mm and a height of 7 mm, the dielectric cover 320 has a height W of 10 mm, and the dielectric constant ∈ᵣ of the plasma varies as −10, −20, −40, and −60. The simulation results showed that when the dielectric cover 320 has a fixed thickness of 10 mm, the electric field concentration does not occur near the metal electrode 310 even for the high density.

### (Experiment)

Thus, inventors had experiments based on the above simulation results. Experiments were performed for the following four plasma conditions.

(1) Ar single gas: 3, 1, 0.5, 0.1, 0.05 Torr.
(2) Ar/O₂ mixed gas: Ar/O₂=160/40, 100/100, 0/200 sccm.
(3) Ar/N₂ mixed gas: Ar/N₂=160/40, 100/100, 0/200 sccm.
(4) Ar/NF₃ mixed gas: Ar/NF₃=180/20, 160/40, 100/100 sccm.

Notable points of the experiment results will be briefly described below. For the metal electrode 310 of a cone, the electric field concentration does not occur near the metal electrode 310. Additionally, the electric field distribution depends little on the Ar gas pressure and the gas species such as O₂, N₂, and NF₃. Good results are thus provided. For the metal electrode 310 of a hemisphere, and the supply of Argon gas along with the O₂ gas or the NF₃ gas, the electric field distribution depends relatively highly on the pressures of the O₂ and NF₃. For the metal electrode 310 being attached with the dielectric cover 320 to provide a cone, the dielectric cover 320 (here, alumina) has lower plasma brightness than the metal electrode 310. The inventors also recognized that the brightness of the aluminum portion of the metal electrode 310 depends on the gas species. The basic shape has a relatively high dependence on the pressure of O₂.

In view of the considerations, the inventors had the following conclusions. First, the metal electrode 310 is preferably formed into a generally-cone shape or a generally-hemisphere shape not to induce the electric field concentration. The generally-cone shape is more preferable. The metal electrode 310 is preferably attached with the dielectric cover 320 to allow the exposed surface of the metal electrode 310 and the dielectric cover 320 to have a generally-cone shape. The end of the dielectric cover 320 is preferably formed flat because the flat end induces a less electric field concentration than a non-flat end. The inventors also derived that it is more preferable that the dielectric cover 320 having a flat end has a height of 10 mm or less in a direction perpendicular to the substrate G.

### (Protection Film)

The surface of the metal electrode 310 is covered by a protection film of highly corrosive-resistant yttria (Y₂O₃), alumina (Al₂O₃), or Teflon (registered trademark). This may reduce the corrosion of the metal electrode 310 by corrosive gases such as an F-based gas (fluorine radical) and a chlorine-based gas (chlorine radical).

Materials of the protection film will be specifically described. The protection film deposited on the surface of the metal electrode 310 may be made of an oxide of aluminum-based metal. The protection film may have a thickness of 10 nm or more. The amount of water discharged from the film may be 1E18 molecules/cm² or less (1×10¹⁸/cm² or less). Note that the following discussion uses the E-notation to represent the molecular number.

The discharged water is due to the surface-adsorbed water of the metal oxide film. The amount of discharged water is proportional to the effective surface area of the metal oxide film. The amount of discharged water may thus be effectively reduced by minimizing the effective surface area. The metal oxide film is thus preferably a barrier metal oxide film, which has no pores on the surface.

When aluminum-based metal with some elements being reduced in their content is applied with a specific chemical conversion bath, a metal oxide film containing less void or gas pocket is formed. The oxide film may thus have less crack generation when heated. The film may thus be highly corrosive resistant for a chemical solution and a halogen gas such as nitric acid and fluorine, and particularly a chlorine gas.

The amount of water discharged from the metal oxide film refers to the number of water molecules per unit area [molecules/cm²] discharged from the film while the film is held at 23° C. for 10 hours and then at 200° C. for 2 hours (the amount is also measured during the temperature rise). The amount of discharged water may be measured using, for example, the atmospheric pressure ionization mass spectrometer (e.g., Renesas Eastern Japan UG-302P).

Preferably, the metal oxide film is prepared by anodic oxidation of aluminum-based metal high-purity aluminum based metal in a chemical conversion bath of pH 4 to 10. The chemical conversion bath preferably includes at least one selected from the group consisting of nitric acid, phosphoric acid, organic carboxylic acid, and salt thereof. The chemical conversion bath preferably contains a nonaqueous solvent. The metal oxide film is preferably heated at 100° C. or more after the anodic oxidation. For example, the metal oxide film may be annealed in a heating furnace at 100° C. or more. Note, however, that the metal oxide film is more preferably heated at 150° C. or more after the anodic oxidation.

The metal oxide film may have other layers formed thereon and/or thereunder as necessary. For example, the metal oxide film may have thereon a thin film made of one or more selected from metal, cermet, and ceramic to form a multilayer structure.

Note that the aluminum-based metal refers to metal including aluminum in an amount of 50 wt % or more. The aluminum-based metal may also include pure aluminum. Preferably, the aluminum-based metal includes aluminum in an amount of 80 wt % or more, more preferably 90 wt % or more, and more preferably 94 wt % or more. The aluminum-based metal preferably includes at least one metal selected from the group consisting of magnesium, titanium, and zirconium.

The high-purity aluminum based metal refers to aluminum-based metal with a total content of specific elements (iron, copper, manganese, zinc, and chromium) being 1% or less. The high-purity aluminum based metal preferably includes at least one metal selected from the group consisting of magnesium, titanium, and zirconium.

Thus, in the plasma processing system 10 in this embodiment, the metal electrode 310 is coupled to the coaxial waveguide 315 via the through-hole 305a of the dielectric plate 305. Additionally, the metal electrode 310 projects from the inner conductor 315a and is exposed on the surface of the dielectric plate 305 facing the substrate. The metal electrode 310 may thus be used to securely hold the dielectric plate 305. The metal electrode 310 may be provided with the dielectric cover 320 on one surface thereof. This may reduce the electric field near the metal electrode, thereby increasing the plasma uniformity.

In the plasma processing system 10 in this embodiment, the dielectric plate includes 224 dielectric plates 305. The dielectric plate thus includes a plurality of dielectric plates 305. The plasma processing system 10 may thus facilitate the maintenance such as the parts replacement and may be highly extensible corresponding to a larger substrate.

### Modification of First Embodiment

Modifications 1 and 2 of the metal electrode 310 of the first embodiment will be described.

### Modification 1

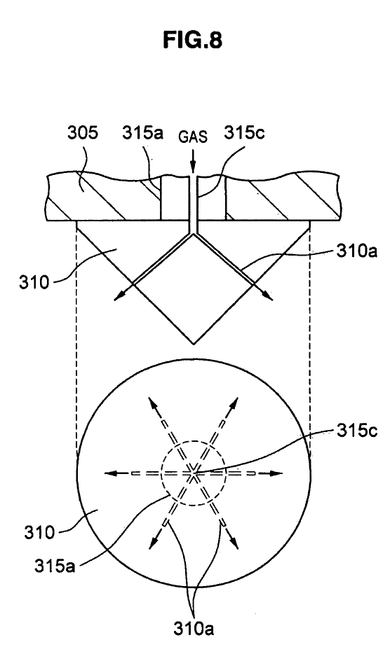

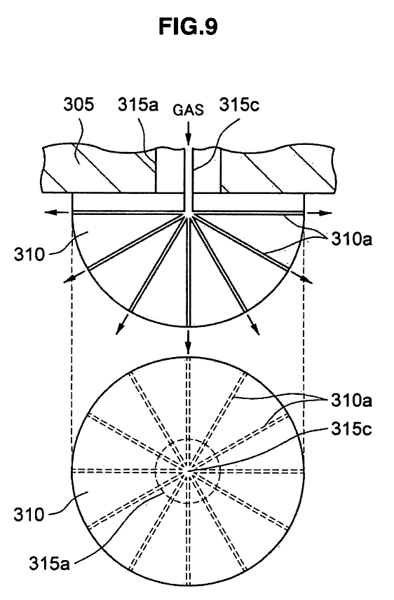

The simulation results show that of the exposed portion of the metal electrode 310, the surface parallel to the substrate G induces the electric field concentration. It is thus preferable that the exposed portion of the metal electrode 310 has a shape that does not have a surface parallel to the substrate G. The modification includes, for example, a cone as shown in FIG. 8. The modification may also provide a hemisphere as shown in FIG. 9. The metal electrode 310 in FIGS. 8 and 9 has advantages including a lower cost due to no dielectric cover attached to the electrode 310 and less electric field concentration due to no surface parallel to the substrate G.

When the exposed portion of the metal electrode 310 has a cone shape as shown in FIG. 8, for example, six gas passages 310a may be provided at regular intervals to introduce the gas down from the gas passages 310a at 45 degrees with respect to the vertical direction. The end of the cone in FIG. 8 may be rounded to reduce the electric field concentration more effectively.

When the exposed portion of the metal electrode 310 has a hemisphere shape as shown in FIG. 9, for example, the gas passages 310a may be provided radially at regular intervals to introduce the gas radially from the passages 310a.

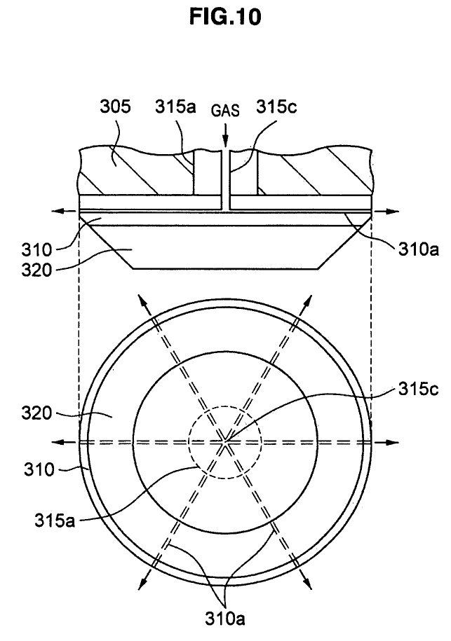

With reference to FIG. 10, the gas passage 310a in the metal electrode 310 may be formed to introduce the gas in a direction parallel to the substrate G. Alternatively, the gas passage 310a may be formed to introduce the gas in a direction perpendicular to the substrate G. The dielectric cover 320 in FIG. 10 is made of alumina ceramics.

When the exposed portion of the metal electrode 310 is provided with the dielectric cover 320 made of porous ceramic, the gas may be introduced from the gas passage 310a in the metal electrode 310 into the processing chamber U via the dielectric cover 320, as shown in FIG. 6.

### Modification 2

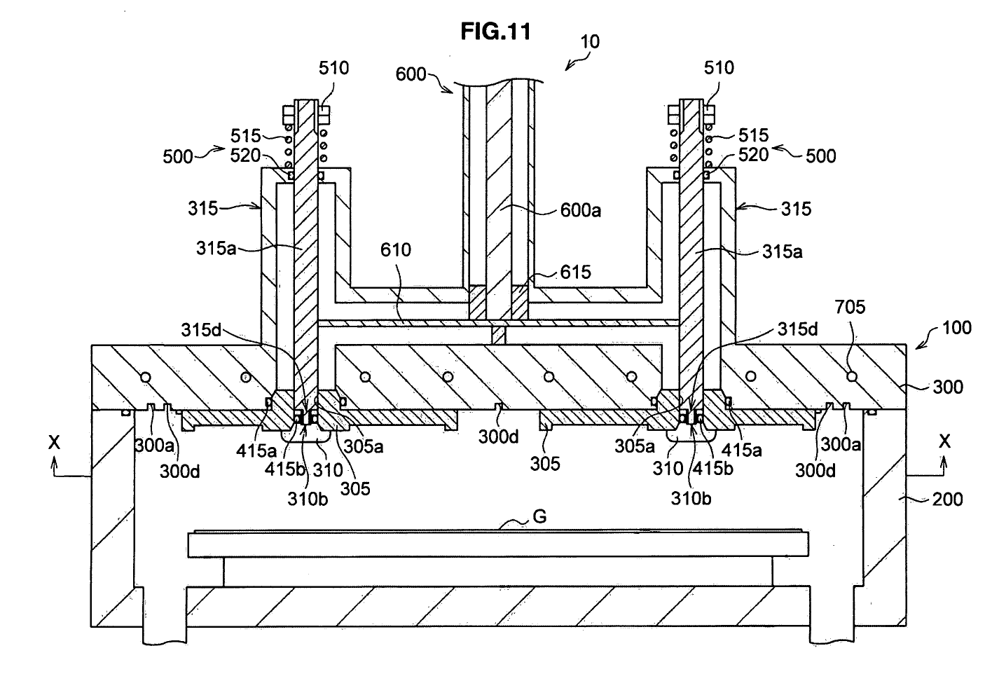

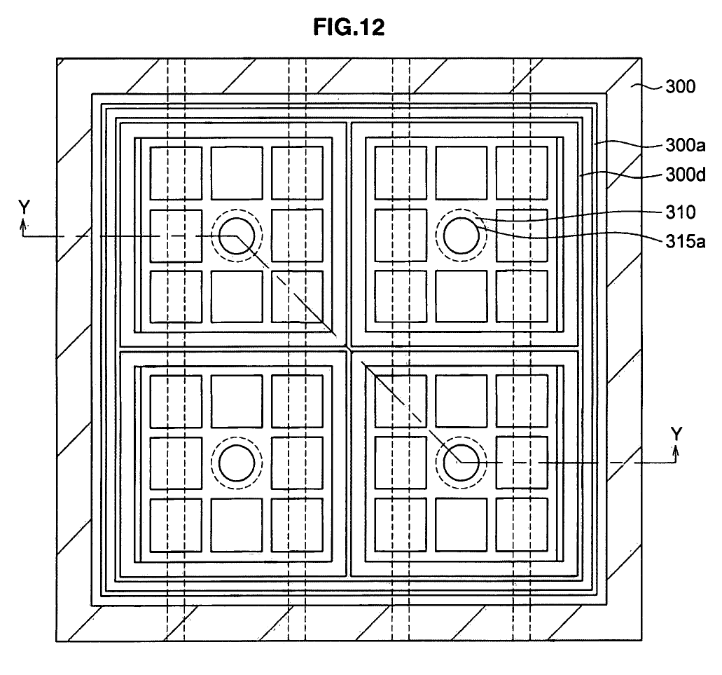

FIG. 12 shows the cross-sectional view taken along the line X-X in FIG. 11. FIG. 11 shows the cross-sectional view taken along the line Y-Y in FIG. 12. With reference to FIG. 11, the metal electrode 310 has a basal portion that extends into the through-hole 305a of the dielectric plate 305. Additionally, the inner conductor 315a of the coaxial waveguide 315 and the metal electrode 310 are screwed and coupled to each other using a male screw 315d at the end portion of the inner conductor 315a and using a female screw 310b at the basal portion of the metal electrode 310.

With reference to FIG. 6, which shows the dielectric ring 410 and the O-ring 415b, the O-ring 415b is first fitted in a space and then the dielectric ring 410 is attached. During attaching the dielectric ring 410, it may damage the O-ring 415b. In the structure in FIG. 11, the dielectric plate 305 tapers at the top. The dielectric plate 305 may thus be fitted more smoothly and the dielectric plate 305 may less damage the O-ring 415b during fitting the plate 305.

In the modification, the dielectric plate 305 and the dielectric ring 410 in FIG. 3 may be integrated as shown in FIG. 11. The O-ring 415b may be provided between the inner surface of the dielectric plate 305 and the metal electrode 310, and the O-ring 415a may be provided between the peripheral surface of the dielectric plate 305 and the lid 300. Again, the metal electrode 310 and the inner conductor 315a may securely hold the dielectric plate 305 on the ceiling, thereby providing a vacuum seal of the interior of the processing chamber U.

In the above embodiments, the operations of the elements are related to each other. The operations may thus be replaced with a series of operations in consideration of the relations. Such a replacement may convert the embodiments of the plasma processing system to embodiments of a method of using a plasma processing system and a method of cleaning a plasma processing system.

### (Frequency Limitation)

The plasma processing system 10 according to each of the above embodiments may be used to output a microwave at a frequency of 1 GHz or less from the microwave source 900, thereby providing good plasma processing. The reason is described below.

The plasma CVD process uses a chemical reaction to deposit a thin film on the substrate surface. In the plasma CVD process, a film is adhered to both of the substrate surface and the processing chamber inner surface. The yield is decreased when the film adhered to the inner surface of the processing chamber is peeled off and deposited on the substrate. An impurity gas from the film adhered to the inner surface of the processing chamber may be incorporated in the thin film, thus degrading the film quality. For the high quality process, the inner surface of the chamber should be regularly cleaned.

The F radicals are often used to remove the silicon oxide film and the silicon nitride film. The F radicals may etch these films quickly. The F radicals may be generated by exciting a plasma in an F containing gas such as NF₃ or SF₆ to decompose the gas molecules. When a mixed gas including F and O is used to excite the plasma, the F and O recombine with electrons in the plasma, thus reducing the electron density of the plasma. Particularly, when a gas including F, the F having the highest electronegativity of all substances, is used to excite the plasma, the electron density is significantly reduced.

To prove this, the inventors generated a plasma and measured the electron density under the condition of at a microwave frequency of 2.45 GHz, a microwave power density of 1.6 W cm⁻², and a pressure of 13.3 Pa. The results showed that the electron density in the Ar gas was 2.3×10¹² cm⁻³, while the density in the NF₃ gas was 6.3×10¹⁰ cm⁻³, which was less than one-tenth of that in the Ar gas.

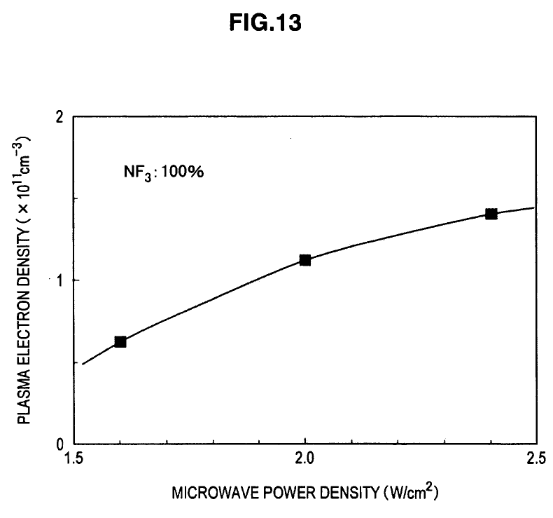

With reference to FIG. 13, as the microwave power density increases, the plasma electron density increases. Specifically, when the power density increases from 1.6 W/cm² to 2.4 W/cm², the plasma electron density increases from 6.3×10¹⁰ cm⁻³ to 1.4×10¹¹ cm⁻³.

When a microwave of 2.5 W/cm² or more is applied, it is more likely for the dielectric plate to be heated and cracked or the abnormal discharge to occur in the chamber, thereby leading to poor economy. It is thus practically difficult to provide an electron density of 1.4×10¹¹ cm⁻³ or more using the NF₃ gas. Specifically, to generate a uniform and stable plasma using an NF₃ gas having an extremely low electron density, the surface wave resonance density nₛ should be 1.4×10¹¹ cm⁻³ or less.

The surface wave resonance density nₛ represents the lowest electron density at which the surface wave may be propagated between the dielectric plate and the plasma. When the electron density is lower than the surface wave resonance density nₛ, the surface wave may not be propagated, thus exciting only an extremely nonuniform plasma. A cut-off density n_{c} is shown in the expression (1). The surface wave resonance density nₛ is proportional to the cut-off density n_{c} as shown in the expression (2).

n_{c}=∈₀mₑω²/e² (1)

nₛ=n_{c}(1+∈ᵣ) (2)

where ∈₀ is the dielectric constant of vacuum, mₑ is the electron's mass, ω is a microwave angle frequency, e is the elementary electric charge, and ∈ᵣ is the relative permittivity of the dielectric plate.

The expressions (1) and (2) show that the surface wave resonance density nₛ is proportional to the square of the microwave frequency. This means that the lower frequency may be selected to propagate the surface wave at a lower electron density and thus provide a uniform plasma. For example, when the microwave frequency is decreased to ½, even the electron density decreased to ¼ may provide a uniform plasma. The reduction of the microwave frequency is thus extremely effective to enlarge the process window.

At a frequency of 1 GHz, the surface wave resonance density nₛ equals the practical electron density of 1.4×10¹¹ cm⁻³ for the NF₃ gas. Specifically, when the microwave frequency is 1 GHz or less, any gas may be used to excite a uniform plasma having a practical power density.

Thus, by allowing the microwave source 900 to output a microwave at a frequency of 1 GHz or less, for example, good plasma processing may be applied to the target object (for example, substrate G).

A method of using a plasma processing system may include, for example: outputting an microwave at a frequency of 1 GHz or less from the microwave source 900 in the plasma processing system 10 in the above embodiments; transferring the microwave from the microwave source 900 through the coaxial waveguide (for example, the coaxial waveguide 600 or 315); transmitting the electromagnetic wave transferred from the coaxial waveguide 315 through the dielectric plate 305 held on the interior wall of the processing chamber 100 and discharging the electromagnetic wave into the processing chamber 100, the dielectric plate 305 being held on the interior wall by the metal electrode 310, the metal electrode 310 being coupled to the inner conductor 315a of the coaxial waveguide via the through-hole 305a formed on the dielectric plate 305, at least a portion of the metal electrode 310 being adjacent to the surface of the dielectric plate 305 that faces the target object, and the metal electrode 310 being exposed on the surface of the dielectric plate that faces the target object; and exciting a process gas introduced into the processing chamber 100 using the discharged electromagnetic wave and applying a desired plasma processing to the target object.

A method of cleaning a plasma processing system may include, for example: outputting an microwave at a frequency of 1 GHz or less from the microwave source 900 in the plasma processing system 10 in the above embodiments; transferring the microwave from the microwave source 900 through the coaxial waveguide (for example, the coaxial waveguide 600 or 315); transmitting the electromagnetic wave transferred from the coaxial waveguide 315 through the dielectric plate 305 held on the interior wall of the processing chamber 100 and discharging the electromagnetic wave into the processing chamber 100, the dielectric plate 305 being held on the interior wall by the metal electrode 310, the metal electrode 310 being coupled to the inner conductor 315a of the coaxial waveguide via the through-hole 305 formed on the dielectric plate 305, at least a portion of the metal electrode 310 being adjacent to the surface of the dielectric plate 305 that faces the target object, and the metal electrode 310 being exposed on the surface of the dielectric plate that faces the target object; and exciting a cleaning gas introduced into the processing chamber 100 using the discharged electromagnetic wave and cleaning the plasma processing chamber.

The preface in “Microwave Plasma Technology,” by The Institute of Electrical Engineers of Japan & the Investigation Committee on Microwave Plasma, Ohmsha, Ltd. (Sep. 25, 2003) describes “the ‘microwave band’ refers to a frequency region of 300 MHz or more in the UHF band.” In the present specification, therefore, the frequency of the microwave refers to 300 MHz or more.

Although in the above embodiments, the microwave source 900 outputs a microwave at 915 MHz, other microwave sources that output microwaves at 896 MHz, 922 MHz, and 2.45 GHz may also be used. Noted that the microwave source corresponds to an electromagnetic source that outputs an electromagnetic wave

Each member and the relation between the members in each embodiment will be briefly summarized below. The exposed surface of the metal electrode may be formed, for example, as a generally-cone shape or a generally-hemisphere shape.

The exposed portion of the metal electrode may be adjacent to a portion or all of the surface of the dielectric plate that faces the target object. The metal electrode may thus securely hold the dielectric plate.

At least a surface of the exposed portion of the metal electrode that is generally parallel to the target object may be covered by the dielectric cover. The electric field is less likely to concentrate on the dielectric cover surface. The exposed portion of the metal electrode may thus be covered by the dielectric cover to reduce the electric field concentrate on the surface of the metal electrode near the feed point. This may avoid the generation of the plasma having a high density near the metal electrode and thus generate a uniform plasma.

The dielectric cover may be made of porous ceramic. The gas may be flowed through space between the pores of the dielectric cover made of porous ceramic and be introduced into the processing chamber.

The exposed surfaces of the metal electrode and the dielectric cover may be formed into a generally-cone shape. The dielectric cover may have a flat end. The height of the dielectric cover in a direction perpendicular to the target object may be 10 mm or less. The electric field does not concentrate on the surface of the dielectric cover, thereby generating a uniform plasma and effectively reducing the metal contamination.

The through-hole of the dielectric plate may be formed at a generally center of the dielectric plate. The metal electrode may thus be used to hold the dielectric plate with a good balance. The electromagnetic wave may be supplied uniformly into the processing chamber through the dielectric plate from the coaxial waveguide.

The surface of the metal electrode may be covered by a protection film. For example, the surface of the metal electrode may be protected by a protection film made of highly corrosive resistant materials such as yttria (Y₂O₃), alumina (Al₂O₃), and Teflon (registered trademark). This may reduce the corrosion of the metal electrode by corrosive gases such as the F-based gas (fluorine radical) and the chlorine-based gas (chlorine radical).

The coaxial waveguide may have a gas introduction path formed therein for flowing a gas. The metal electrode may have a gas passage formed therein. The gas passage may communicate with the gas introduction path formed in the coaxial waveguide and introduce the gas flowing through the gas introduction path into the processing chamber.

The gas may thus be introduced into the processing chamber through the gas passage in the metal electrode. Because the metal does not transmit the electromagnetic wave, the gas is not excited in the gas passage in the metal electrode. The generation of a plasma in the metal electrode may thus be avoided.

The gas passage in the metal electrode may be formed to introduce the gas in a direction generally parallel to the target object. The gas passage may also be formed to introduce the gas in a direction generally perpendicular to the target object. The gas passage may also be formed to radially introduce the gas.

The gas may be introduced into the processing chamber directly from the gas passage in the metal electrode. The gas may also be introduced into the processing chamber from the gas passage through the dielectric cover made of the porous ceramic. Particularly, when the gas is supplied through the porous ceramic, the gas reduces the speed as it flows through space between the pores of the porous ceramic and is then introduced uniformly at a reduced speed from the surface of the porous ceramic. This may reduce unnecessary propagation of the gas in the processing chamber, thereby generating a desired plasma without the gas excessively dissociated.

The dielectric plate may be made of alumina.

The dielectric plate may include a plurality of dielectric plates. The metal electrode may be provided in a plurality corresponding to the respective dielectric plates. Because the dielectric plate includes a plurality of dielectric plates, a plasma processing system may thus be provided that may facilitate the maintenance such as the parts replacement and be highly extensible corresponding to a larger substrate.

Each of the dielectric plates may be formed to have a generally rectangular surface facing the target object. Each of the dielectric plates may also be formed to have a generally square surface facing the target object. Each dielectric plate thus has a symmetrical shape. The electromagnetic wave is thus uniformly discharged from the dielectric plates disposed on the whole ceiling. A more uniform plasma may thus be generated under the dielectric plates.

The electromagnetic source may output the electromagnetic wave at a frequency of 1 GHz or less. The cut-off density may therefore be reduced and thus increase the process window, allowing for a variety of processes in one system.

During the process, the side of the dielectric plate may be in contact with the plasma. When the dielectric plate is in contact with other members around the dielectric plate, a gap may occur and a plasma may enter the gap, thus generating the abnormal discharge. Elimination of the gap needs highly accurate machining. This results in high cost. According to an embodiment of the invention, the side of the dielectric plate is in contact with the plasma. No gap thus exists around the dielectric plate, thereby eliminating highly accurate machining and reducing the cost.

Thus, the preferred embodiments of the present invention have been described with reference to the accompanying drawings, but it will be appreciated that the present invention is not limited to the disclosed embodiments. It should be understood by those skilled in the art that various modifications, combinations, sub-combinations and alterations may occur depending on design requirements and other factors insofar as they are within the scope of the appended claims or the equivalents thereof.

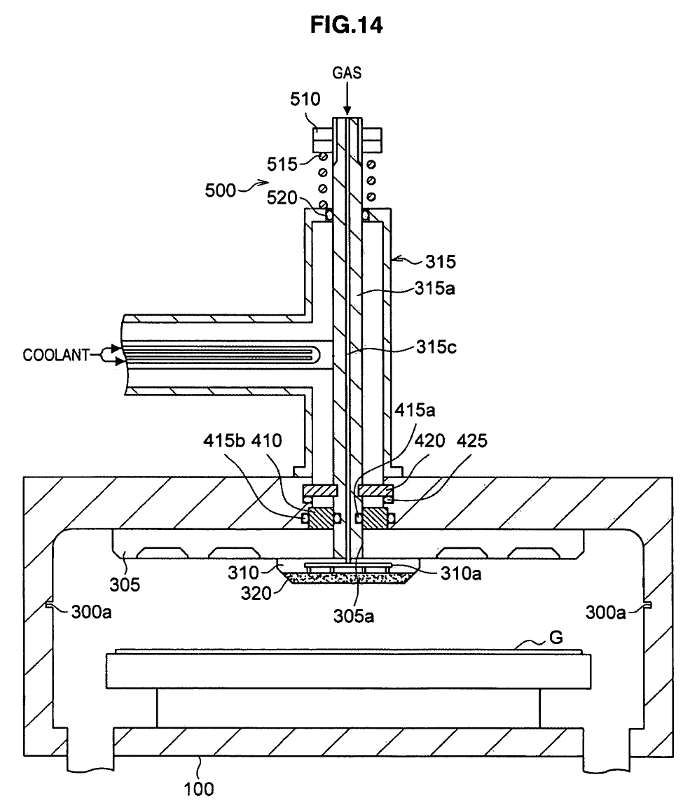

For example, the dielectric plate 305 in the plasma processing system according to the present invention may include a plurality of square dielectric plates. The dielectric plate 305 may also be a single large-area circular dielectric plate as shown in FIG. 14.

One metal electrode 310 coupled to one inner conductor 315a thus provides one dielectric plate 305 on the ceiling of the processing chamber 100. As in the plasma processing system having a plurality of dielectric plates 305, the side of the dielectric plate 305 is in contact with the plasma during the process.

This may thus avoid the abnormal discharge that occurs when the side of the dielectric plate 305 is in contact with other members (such as a metal frame) and the plasma enters the gap between the dielectric plate 305 and the members.

A dielectric ring 420 is provided above the dielectric ring 410 and between the lid 300 and the inner conductor 315a. The inner conductor 315a passes through the center of the dielectric material 420. A portion of the peripheral surface and the inner surface of the dielectric ring 420 is embedded in the lid 300 and the inner conductor 315a. An O-ring 425 is provided between the dielectric ring 420 and the lid 300. The O-ring 425 is provided on the surface (bottom surface) of the dielectric material 420 that faces the inside of the processing chamber.

With reference to FIG. 14, the plasma processing system 10 includes the O-ring 425 to raise the dielectric plate 305. The elastic force (repulsive force) of the O-ring 425 against the processing chamber 100 may lift the inner conductor 315a of the coaxial waveguide away from the processing chamber 100.

The two dielectric rings 410 and 420 may support, at two points, the inner conductor 315a holding the dielectric plate 305. This may reduce the shaft swing of the coaxial waveguide 315. The spring elastic force and the guide function of the inner conductor 315a may thus securely fasten the dielectric plate 305 on the interior wall of the lid 300. This may avoid the abnormal discharge caused by the plasma entering the gap between the interior wall of the lid 300 and the dielectric plate 305, thereby generating a uniform and stable plasma.

The plasma processing system according to the present invention may also apply to processing of various substrates such as a large-area glass substrate, a circular silicon wafer, and a square silicon-on-insulator (SOI) substrate.

The plasma processing system according to the present invention may also apply to various plasma processes such as a deposition process, a propagation process, an etching process, and an ashing process.

What is claimed is:

1. A plasma processing system that excites a gas using an electromagnetic wave and applies a plasma process to a target object, the system comprising:
a processing chamber;
an electromagnetic source that outputs an electromagnetic wave;
a conductor rod that transfers the electromagnetic wave from the electromagnetic source;
a dielectric plate that has a through-hole formed thereon, the dielectric plate transmitting the electromagnetic wave transferred by the conductor rod into the processing chamber; and
a metal electrode that is coupled to the conductor rod via the through-hole formed on the dielectric plate, at least a portion of the metal electrode being adjacent to the surface of the dielectric plate that faces the target object, and the metal electrode being exposed on the surface of the dielectric plate that faces the target object,
a surface of the exposed surface of the metal electrode being covered by a dielectric cover.

2. A plasma processing system that excites a gas using an electromagnetic wave and applies a plasma process to a target object, the system comprising:
a processing chamber;
an electromagnetic source that outputs an electromagnetic wave;
a conductor rod that transfers the electromagnetic wave from the electromagnetic source;
a dielectric plate that has a through-hole formed thereon, the dielectric plate transmitting the electromagnetic wave transferred by the conductor rod into the processing chamber; and
a metal electrode that is coupled to the conductor rod via the through-hole formed on the dielectric plate, at least a portion of the metal electrode being adjacent to the surface of the dielectric plate that faces the target object, and the metal electrode being exposed on the surface of the dielectric plate that faces the target object,
the exposed surface of the metal electrode does not include a surface that is substantially parallel to the target object.

3. The plasma processing system according to claim 1, wherein
the metal electrode has a larger diameter than the conductor rod.

4. The plasma processing system according to claim 1, wherein
the exposed surface of the metal electrode is formed into a substantially-cone shape or a substantially-hemisphere shape.

5. The plasma processing system according to claim 1, wherein
the surface of the exposed surface of the metal electrode that is substantially parallel to the target object is covered by the dielectric cover.

6. The plasma processing system according to claim 1, wherein
the dielectric cover is made of porous ceramic.

7. The plasma processing system according to claim 1, wherein
the through-hole of the dielectric plate is formed at a substantially center of the dielectric plate.

8. The plasma processing system according to claim 1, wherein
the surface of the metal electrode is covered by a protection film.

9. The plasma processing system according to claim 1, wherein
the conductor rod has a gas introduction path formed therein for flowing a gas, and
the metal electrode has a gas passage formed therein, the gas passage communicating with the gas introduction path formed in the conductor rod, and the gas passage introducing the gas flowing in the gas introduction path into the processing chamber.

10. The plasma processing system according to claim 9, wherein
the gas passage is formed in the metal electrode to introduce the gas in a direction substantially parallel to the target object.

11. The plasma processing system according to claim 9, wherein
the gas passage is formed in the metal electrode to introduce the gas in a direction substantially perpendicular to the target object.

12. The plasma processing system according to claim 9, wherein
the gas passage is formed in the metal electrode to radially introduce the gas.

13. The plasma processing system according to claim 9, wherein
the gas is directly introduced from the gas passage into the processing chamber.

14. The plasma processing system according to claim 9, wherein
the gas is introduced from the gas passage into the processing chamber via the dielectric cover.

15. The plasma processing system according to claim 1, wherein
the dielectric plate is provided in a plurality and the metal electrode is provided in a plurality corresponding to the respective dielectric plates.

16. The plasma processing system according to claim 15, wherein each of the dielectric plates is formed to have a substantially rectangular surface facing the target object.

17. The plasma processing system according to claim 16, wherein each of the dielectric plates is formed to have a substantially square surface facing the target object.

18. The plasma processing system according to claim 1, wherein
the electromagnetic source outputs an electromagnetic wave at a frequency of 1 GHz or less.

19. The plasma processing system according to claim 1, wherein
during the process, the side of the dielectric plate is in contact with the plasma.

20. An antenna comprising:
a conductor rod that transfers an electromagnetic wave;
a dielectric plate that has a through-hole formed therein, the dielectric plate transmitting the electromagnetic wave transferred by the conductor rod into the processing chamber; and
a metal electrode that is coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object,
a surface of the exposed surface of the metal electrode being covered by a dielectric cover.

21. An antenna comprising:
a conductor rod that transfers an electromagnetic wave;
a dielectric plate that has a through-hole formed therein, the dielectric plate transmitting the electromagnetic wave transferred by the conductor rod into the processing chamber; and
a metal electrode that is coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object,
the exposed surface of the metal electrode does not include a surface that is substantially parallel to the target object.

22. A method of using a plasma processing system, the method comprising:
outputting an electromagnetic wave at a frequency of 1 GHz or less from an electromagnetic source,
transferring the electromagnetic wave through a conductor rod;
transmitting the electromagnetic wave transferred from the conductor rod through a dielectric plate held on an interior wall of a processing chamber and discharging the electromagnetic wave into the processing chamber, the dielectric plate being held on the interior wall by a metal electrode, the metal electrode being coupled to the conductor rod via the through-hole formed on the dielectric plate, at least a portion of the metal electrode being adjacent to the surface of the dielectric plate that faces a target object, and the metal electrode being exposed on the surface of the dielectric plate that faces the target object; and
exciting a process gas introduced into the processing chamber using the discharged electromagnetic wave and applying a desired plasma processing on the target object.

23. A method of cleaning a plasma processing system, the method comprising:
outputting an electromagnetic wave at a frequency of 1 GHz or less from an electromagnetic source,
transferring the electromagnetic wave through a conductor rod;
transmitting the electromagnetic wave transferred from the conductor rod through a dielectric plate held on an interior wall of a processing chamber and discharging the electromagnetic wave into the processing chamber, the dielectric plate being held on the interior wall by a metal electrode, the metal electrode being coupled to the conductor rod via a through-hole formed on the dielectric plate, at least a portion of the metal electrode being adjacent to the surface of the dielectric plate that faces a target object, and the metal electrode being exposed on the surface of the dielectric plate that faces the target object; and
exciting a cleaning gas introduced into the processing chamber using the discharged electromagnetic wave and cleaning the plasma processing chamber.

24. The plasma processing system according to claim 5, wherein
the exposed surfaces of the metal electrode and the dielectric cover are formed into a substantially cone shape.

25. The plasma processing system according to claim 24, wherein
the dielectric cover has a flat end.

26. The plasma processing system according to claim 25, wherein the height of the dielectric cover in a direction perpendicular to the target object is 10 mm or less.
